(19) United States
(12) Patent Application Publication
(10) Pub. No.: US 2026/0354025 A1
(43) Pub. Date: Nov. 5, 2026

(54) MULTI-LAYERED BIDIRECTIONAL SOLID-STATE COOLER

(71) Applicant: KOREA INSTITUTE OF SCIENCE AND TECHNOLOGY, Seoul (KR)

(72) Inventors: Sunghoon HUR, Seoul (KR); Gimin PARK, Seoul (KR); Byoungjin YOON, Seoul (KR); Jeyeon LEE, Seoul (KR)

(21) Appl. No.: 19/570,162

(22) Filed: Mar. 18, 2026

(30) Foreign Application Priority Data
Apr. 30, 2025 (KR) 10-2025-0057803

(51) Int. Cl. H10N 15/10; F25B 21/00

(52) U.S. Cl. CPC H10N 15/15; F25B 21/00; F25B 2321/001

(57) ABSTRACT

A multi-layered bidirectional solid-state cooler is disclosed. The multi-layered bidirectional solid-state cooler includes an electrocaloric layer, a first thermal switch layer disposed on a first surface of the electrocaloric layer, and a second thermal switch layer disposed on a second surface of the electrocaloric layer, wherein the electrocaloric layer performs heat generation or heat absorption by decreasing or increasing entropy depending on whether or not an electric field is applied, and the first thermal switch layer and the second thermal switch layer each cover ⅔ or more of the first surface and the second surface of the electrocaloric layer, and thermal conductivity changes depending on whether or not an electric field is applied or intensity of the electric field.

### CROSS-REFERENCE TO RELATED APPLICATION

This application claims priority to and the benefit of Korean Patent Application No. 10-2025-0057803 filed with the Korean Intellectual Property Office on Apr. 30, 2025, the entire contents of which are incorporated herein by reference.

### BACKGROUND

### (a) Field

The present disclosure relates to a multi-layered bidirectional solid-state cooler capable of performing cooling or heating by stacking solid materials.

### (b) Description of the Related Art

As a representative method of cooling technology, a vapor compression cooling cycle is widely used. This is a method in which a refrigerant absorbs heat from a heat source and releases it to the outside air while repeating evaporation and condensation, and it is used in most cooling devices such as refrigerators and air conditioners. The cycle generally consists of the following four main processes:
Compressor: Compresses low-temperature and low-pressure refrigerant vapor into high-temperature and high-pressure.
Condenser: High-temperature and high-pressure refrigerant condenses and releases heat to the outside.
Expansion Valve: Drops the temperature by lowering the pressure of the refrigerant.
Evaporator: Absorbs surrounding heat as the refrigerant evaporates.

Although this method has been verified for a long time, it has the following problems.

First, Freon-based refrigerants (CFCs, HCFCs) used as refrigerants may cause ozone layer depletion and global warming, and since the coefficient of performance (COP) cannot reach 100%, energy loss occurs, and regular maintenance is required, and problems such as refrigerant leakage, component failure, noise, and vibration may occur, and since it is bulky and has a wide installation area, it is difficult to apply to an environment with space constraints.

Another method is cooling technology using a thermoelectric element (Peltier element). This utilizes the principle that when two different metals or semiconductors are joined and a current is passed through them, one side is cooled and the other side is heated. Although it has the advantage of being drivable only by electricity without refrigerant or mechanical operation, it has the following problems:

This method has a very low COP, so the cooling efficiency is significantly lower than that of the conventional vapor compression method, and a high current (1 A or more) is required for operation, and accordingly, there is a limitation in maintaining cooling performance due to self-heat generation. In addition, although there is an immediate cooling effect, it is difficult to secure stable cooling performance for a long time.

### SUMMARY

A task to be solved by the embodiments is to provide a solid-based cooler that does not use a refrigerant or is safer.

Another task to be solved by the embodiments is to provide a low-noise cooler capable of cooling in an electrical manner without mechanical operation.

Another task to be solved by the embodiments is to provide a high-density, stacked cooler applicable to even a narrow space.

Another task to be solved by the embodiments is to provide a multi-layered bidirectional solid-state cooler capable of exhibiting continuous cooling performance while maintaining the advantages of an electrical cooling method.

A multi-layered bidirectional solid-state cooler according to an embodiment includes an electrocaloric layer, a first thermal switch layer disposed on a first surface of the electrocaloric layer, and a second thermal switch layer disposed on a second surface of the electrocaloric layer, wherein the electrocaloric layer performs heat generation or heat absorption by decreasing or increasing entropy depending on whether or not an electric field is applied, and the first thermal switch layer and the second thermal switch layer each cover ⅔ or more of the first surface and the second surface of the electrocaloric layer, and thermal conductivity can change depending on whether or not an electric field is applied or the intensity of the electric field.

The electrocaloric layer may include a ceramic material having a complex perovskite structure of a PMN-PT series or a PST series.

The cooler may further include a first electrocaloric layer control electrode and a second electrocaloric layer control electrode disposed on both surfaces of the electrocaloric layer, respectively, and a thermal switch layer control electrode disposed on both surfaces of each of the first and second thermal control layers.

An insulating layer may be disposed between the electrocaloric layer control electrode and the thermal switch layer control electrode.

The electrocaloric layer control electrode and the thermal switch layer control electrode may be integrally formed so that one electrode is used simultaneously for the control of the electrocaloric layer and the thermal switch layer located on both sides.

Cooling can be achieved by repeating an operation cycle in which heat is released and the temperature rise occurs as internal entropy decreases when an electric field is applied to the electrocaloric layer, and heat is absorbed and the temperature drop occurs as internal entropy increases when the electric field is removed.

The first thermal switch layer and the second thermal switch layer may have maximum thermal conductivity when a first voltage is applied, and minimum thermal conductivity when a second voltage is applied.

The second voltage may be 0V.

In the thermal control layer, the alignment state of molecules changes depending on whether or not an electric field is applied or the intensity, and due to this, thermal conductivity can be improved or lowered.

A switch and a power supply voltage are connected between each pair of control electrodes of the electrocaloric layer and the thermal switch layer to selectively control the application or blocking of an electric field.

A multi-layered bidirectional solid-state cooler according to an embodiment includes a plurality of thermal control layers and a plurality of electrocaloric layers disposed between the plurality of thermal control layers, wherein the thermal switch layer and the electrocaloric layer have a structure in which they are alternately stacked, the plurality of electrocaloric layers perform heat generation or heat absorption by decreasing or increasing entropy depending on whether or not an electric field is applied, and the plurality of thermal control layers may change thermal conductivity depending on whether or not an electric field is applied or the intensity of the electric field.

The cooler may further include a plurality of electrocaloric layer control electrodes disposed on both surfaces of each of the plurality of electrocaloric layers, and a plurality of thermal switch layer control electrodes disposed on both surfaces of each of the plurality of thermal control layers.

An insulating layer may be disposed between the electrocaloric layer control electrode and the thermal switch layer control electrode.

The electrocaloric layer control electrode and the thermal switch layer control electrode may be integrally formed so that one electrode is used simultaneously for the control of the electrocaloric layer and the thermal switch layer located on both sides.

The plurality of electrocaloric layers and the plurality of thermal control layers may be capable of independent control by individually connecting a power source and a switch to each control electrode.

A multi-layered bidirectional solid-state cooler according to an embodiment includes a circuit board, a plurality of solid-state cooling elements disposed on the circuit board, and a plurality of electrode connection terminals connecting between the wiring of the circuit board and the plurality of control electrodes of the plurality of solid-state cooling elements,
wherein each of the plurality of solid-state cooling elements includes a plurality of thermal control layers and a plurality of electrocaloric layers disposed between the plurality of thermal control layers, the thermal switch layer and the electrocaloric layer have a structure in which they are alternately stacked, the plurality of electrocaloric layers perform heat generation or heat absorption by decreasing or increasing entropy depending on whether or not an electric field is applied, and the plurality of thermal control layers may change thermal conductivity depending on whether or not an electric field is applied or the intensity of the electric field.

The cooler may further include a separation layer located between the plurality of solid-state cooling elements and composed of an insulating material, and each of the plurality of solid-state cooling elements may be independently controlled.

The circuit board may include a portion composed of a material having excellent thermal conductivity, such as metal, to perform a heat sink function.

The plurality of solid-state cooling elements may be arranged in a 2×2 matrix, a single row arrangement, or an L-shaped arrangement.

The multi-layered bidirectional solid-state cooler may be included in plurality.

According to the embodiments, by applying a cooling method using a solid-state heat transfer medium and a stacked structure without using a refrigerant, environmental pollution problems caused by Freon-based refrigerants can be fundamentally eliminated.

According to the embodiments, since cooling is possible without complicated piping and mechanical devices, miniaturization, weight reduction, and simplification of the entire system are possible.

According to the embodiments, by applying a solid-state heat exchange structure capable of efficient heat dissipation, heat accumulation can be prevented and stable cooling performance can be maintained for a long time.

According to the embodiments, due to the nature of the stacked structure, when a cooling performance improvement is necessary, it is possible to flexibly respond to systems of various capacities and sizes by simply connecting modules in parallel.

### BRIEF DESCRIPTION OF THE DRAWINGS

FIG. 1 is a cross-sectional view of a multi-layered bidirectional solid-state cooler according to an embodiment.

FIG. 2 is a conceptual diagram for showing the operating principle of a multi-layered bidirectional solid-state cooler according to an embodiment.

FIG. 3 is a diagram showing the operation flow of a multi-layered bidirectional solid-state cooler according to an embodiment.

FIG. 4 is a conceptual diagram showing the operation method of a thermal control material applied to the embodiments.

FIG. 5 is an electric field-conductivity relationship graph showing the operation method of a thermal control material applied to the embodiments.

FIG. 6 is a cross-sectional view of a multi-layered bidirectional solid-state cooler according to another embodiment.

FIG. 7 is a diagram showing the operation flow of a multi-layered bidirectional solid-state cooler according to another embodiment.

FIG. 8 is a conceptual diagram showing a process in which cooling proceeds when an electrocaloric material is applied as a single layer and when an electrocaloric material is applied as multiple layers.

FIG. 9 is a cross-sectional view of a multi-layered bidirectional solid-state cooler according to another embodiment.

FIG. 10 is a cross-sectional view of a multi-layered bidirectional solid-state cooler according to another embodiment.

FIG. 11 and FIG. 12 are perspective views of multi-layered bidirectional solid-state coolers according to other embodiments.

### DETAILED DESCRIPTION OF THE EMBODIMENTS

Hereinafter, embodiments of the present invention will be described in detail with reference to the accompanying drawings so that those skilled in the art to which the present invention pertains can easily implement them. However, the present invention may be implemented in various different forms and is not limited to the embodiments described herein.

The drawings and description are to be regarded as illustrative in nature and not restrictive. Like reference numerals designate like elements throughout the specification.

In the drawings, the size and thickness of each component may be arbitrarily shown for convenience of description, and the present invention is not necessarily limited to those shown in the drawings. In the drawings, the thickness of layers, films, plates, regions, etc., may be exaggerated for clarity. In the drawings, the thickness of some layers and regions may be exaggerated for convenience of description.

As used herein, the singular forms “a”, “an” and “the” are intended to include the plural forms as well, unless the context clearly indicates otherwise.

In the specification and claims, the term “and/or” is intended to include any combination of the terms “and” and “or” for its meaning and interpretation. For example, “A and/or B” can be understood to mean “A, B, or A and B”.

In the specification and claims, the phrase “at least one of” is intended to include the meaning of “at least one selected from the group of” for its meaning and interpretation. For example, “at least one of A and B” can be understood to mean “A, B, or A and B”.

Although terms such as first, second, etc. may be used herein to describe various components, these components are not limited by these terms. These terms are only used to distinguish one element from another element. For example, a first component could be termed a second component, and similarly, a second component could be termed a first component, without departing from the scope of the present invention.

When an element such as a layer, film, region, or substrate is referred to as being “on” another element, it can be directly on the other element or intervening elements may also be present. In contrast, when an element is referred to as being “directly on” another element, there are no intervening elements present. In addition, throughout the specification, the term ‘on’ a target element should be understood as being located above or below the target element, and does not necessarily mean being located ‘on the upper side’ based on the direction opposite to gravity.

For example, spatially relative terms such as “below”, “above”, etc. may be used to easily describe the relationship between one element or component and another component as shown in the drawings. Spatially relative terms are intended to include other directions in the device in use or operation in addition to the direction shown in the drawings. For example, if the device shown in the drawings is turned over, a device located ‘below’ another device may be located ‘above’ the other device. Thus, the exemplary term “below” can include both lower and upper positions. The device may also be oriented in other directions, so spatially relative terms may be interpreted differently depending on the direction.

When an element (or region, layer, part, etc.) is referred to as being “connected” or “coupled” to another element in the specification, it may be directly disposed, connected, or coupled to the other element mentioned above, or an intervening element may be disposed therebetween.

The terms “connected to” or “coupled to” may include physical or electrical connection or coupling.

Unless otherwise defined, all terms (including technical and scientific terms) used herein have the same meaning as commonly understood by one of ordinary skill in the art to which this invention belongs. Terms such as those defined in commonly used dictionaries should be interpreted as having a meaning consistent with their meaning in the context of the relevant art and should not be interpreted in an idealized or overly formal sense unless explicitly defined herein.

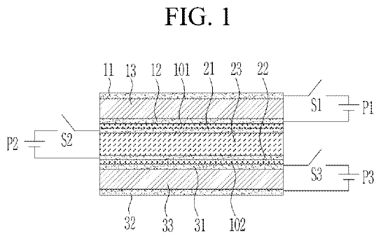

FIG. 1 is a cross-sectional view of a multi-layered bidirectional solid-state cooler according to an embodiment.

A multi-layered bidirectional solid-state cooler according to an embodiment includes an electrocaloric layer 23 and thermal control layers 13, 33 disposed on both sides thereof. Electrocaloric layer control electrodes 21, 22 are disposed on the upper and lower surfaces of the electrocaloric layer 23, and thermal switch layer control electrodes 11, 12, 31, 32 are disposed on the upper and lower surfaces of each of the thermal control layers 13, 33. An insulating layer 101 is disposed between the electrocaloric layer control electrode 21 and the thermal switch layer control electrode 12, and an insulating layer 102 is disposed between the electrocaloric layer control electrode 22 and the thermal switch layer control electrode 31. A power supply voltage P2 and a switch S2 are connected between the two electrocaloric layer control electrodes 21, 22. A power supply voltage P1 and a switch S1 are connected between the two thermal switch layer control electrodes 11, 12, and a power supply voltage P3 and a switch S3 are connected between the two thermal switch layer control electrodes 31, 32.

The insulating layers 101, 102 located between the electrocaloric layer control electrodes 21, 22 and the thermal switch layer control electrodes 12, 31 may be omitted. That is, the electrocaloric layer control electrodes 21, 22 and the thermal switch layer control electrodes 12, 31 may be integrally formed, and one control electrode may be used for both the control of the electrocaloric layer and the control of the thermal switch layer located on both sides thereof.

The electrocaloric layer 23 uses a material whose internal entropy decreases or increases depending on whether or not an electric field is applied, and examples thereof include PMN-PT series or PST (lead scandium tantalite, Pb(ScₓTa₁₋ₓ)O₃) series and the like. When the power supply voltage P2 is applied to the two electrodes 21, 22 on both surfaces of the electrocaloric layer 23, the internal entropy decreases, and accordingly, as heat is released, the temperature of the electrocaloric layer 23 rises. Conversely, when the power supply voltage P2 applied to the electrocaloric layer 23 is blocked, the internal entropy of the electrocaloric layer 23 increases, and accordingly, as ambient heat is absorbed, the temperature of the electrocaloric layer 23 drops.

The PMN-PT series is a material series having a complex perovskite structure and is a composite oxide containing two components: PMN ( Pb(Mg_{1/3}Nb_{2/3})O₃) and PT (PbTiO₃). A general notation for the PMN-PT series is

(1−x)Pb(Mg_{1/3}Nb_{2/3})O₃−xPbTiO₃.

The PST (Lead Scandium Tantalate, Pb(ScₓTa₁₋ₓ)O₃) series is a ferroelectric ceramic of a complex perovskite series.

The thermal control layers 13, 33 use a material whose thermal conductivity changes depending on whether or not an electric field is applied or the intensity of the electric field, and examples thereof include GeTeO₃, PbZrO₃, KNbO₃, PbTiO₃, BifeO₃, PbZrO₃, PbTiZrNbNiO₃, PbZrTiO₃, etc. The thermal control layers 13, 33 have the highest thermal conductivity when a first voltage (e.g., P1, P3) is applied between the two electrodes 11, 12, 31, 32 disposed on both surfaces thereof, and have the lowest thermal conductivity when a second voltage (e.g., 0V) is applied. Although the second voltage is exemplified as 0V in the present embodiment, the voltage at which the thermal conductivity becomes the lowest may not be 0V.

The thermal control layers 13, 33 function as thermal paths that receive and release heat from the electrocaloric layer 23 or transfer and absorb heat from the outside to the electrocaloric layer 23. Therefore, it is preferable that the contact surface between the thermal control layers 13, 33 and the electrocaloric layer 23 be as wide as possible, and it may be appropriate for the thermal control layers 13, 33 to cover at least ⅔ or more of the surface of the electrocaloric layer 23.

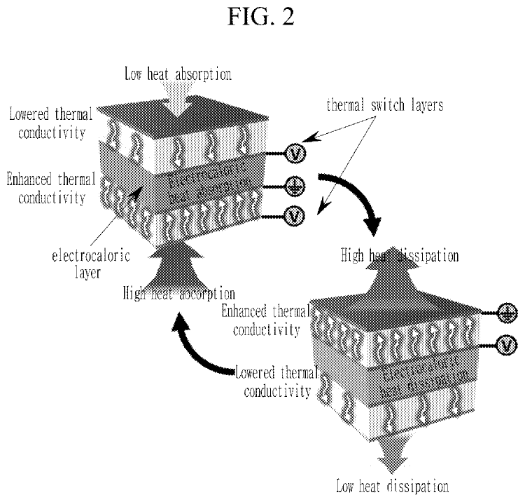

FIG. 2 is a conceptual diagram for showing the operating principle of a multi-layered bidirectional solid-state cooler according to an embodiment.

In the electrocaloric layer 23, when an electric field is applied, internal entropy decreases, thereby releasing heat, and in a state insulated from the outside, the temperature of the electrocaloric layer 23 rises. On the other hand, when the electric field applied to the electrocaloric layer 23 is removed, internal entropy increases, thereby absorbing heat, and in a state insulated from the outside, the temperature of the electrocaloric layer 23 drops.

The thermal control layers 13, 33 have the highest thermal conductivity when a first voltage (e.g., P1, P3) is applied to both ends thereof, and have the lowest thermal conductivity when a second voltage (e.g., 0V) is applied.

Referring to FIG. 2, in a state where the second voltage is applied to the upper thermal switch layer to make the thermal conductivity the lowest and the first voltage is applied to the lower thermal switch layer to make the thermal conductivity the highest, if the voltage applied to the electrocaloric layer is removed, heat is absorbed into the electrocaloric layer through the lower thermal switch layer as the entropy of the electrocaloric layer increases.

Conversely, in a state where the first voltage is applied to the upper thermal switch layer to make the thermal conductivity the highest and the second voltage is applied to the lower thermal switch layer to make the thermal conductivity the lowest, if a voltage is applied to the electrocaloric layer, heat is released as the entropy of the electrocaloric layer decreases, and this heat is released through the upper thermal control layer.

As described above, heat can be moved in one direction by controlling the voltage applied to the electrocaloric layer and the thermal control layers disposed on both surfaces thereof.

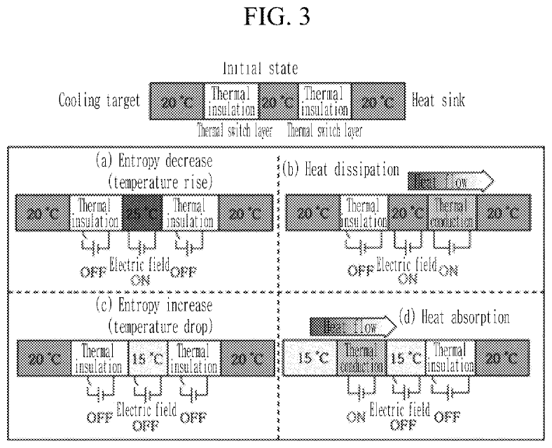

FIG. 3 is a diagram showing the operation flow of a multi-layered bidirectional solid-state cooler according to an embodiment.

Referring to FIG. 3, the operation flow of the multi-layered bidirectional solid-state cooler according to an embodiment will be described in more detail.
(a) Entropy decrease (temperature rise): In a state where the electrocaloric layer 23 is insulated by applying the second voltage (0V, power OFF in the embodiment) to the thermal control layers 13, 33 to make the thermal conductivity minimum, if a power supply voltage is applied (electric field application) to the electrocaloric layer 23, the entropy of the electrocaloric layer 23 decreases while releasing heat, so the temperature of the electrocaloric layer 23 rises.
(b) Heat dissipation: When the first voltage is applied to one of the thermal control layers 13, 33 (e.g., the upper thermal switch layer 13) to make the thermal conductivity maximum, heat accumulated in the electrocaloric layer 23 is released upward through the upper thermal switch layer 13.
(c) Entropy increase (temperature drop): Again, in a state where the electrocaloric layer 23 is insulated by applying the second voltage (0V, power OFF in the embodiment) to the thermal control layers 13, 33 to make the thermal conductivity minimum, if the power supply voltage applied to the electrocaloric layer 23 is blocked (electric field removal), the entropy of the electrocaloric layer 23 increases while absorbing heat, so the temperature of the electrocaloric layer 23 drops.
(d) Heat absorption: Next, when the first voltage is applied to one of the thermal control layers 13, 33 (e.g., the lower thermal switch layer 33) to make the thermal conductivity maximum, since the temperature of the electrocaloric layer 23 is low, heat of a cooling target is absorbed into the electrocaloric layer 23 through the lower thermal switch layer 33.

By repeating this cycle, heat of the cooling target can be absorbed and released to the outside.

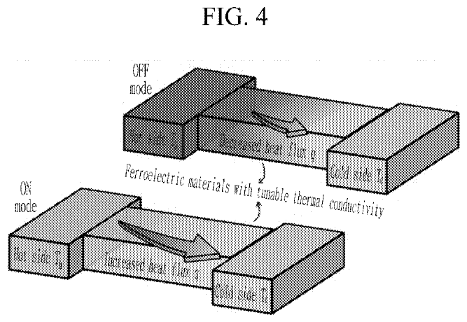

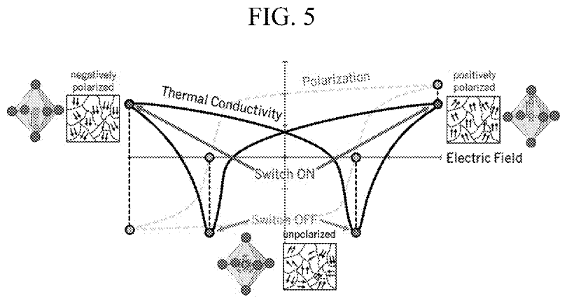

FIG. 4 is a conceptual diagram showing the operation method of a thermal control material applied to the embodiments. FIG. 5 is an electric field-conductivity relationship graph showing the operation method of a thermal control material applied to the embodiments.

Referring to FIG. 4, in the thermal control material constituting the thermal control layers 13, 33, the thermal conductivity is improved (heat flux increase, ON mode) or lowered (heat flux decrease, OFF mode) depending on whether or not an electric field is applied or the intensity of the electric field.

Referring to FIG. 5, such improvement or lowering of thermal conductivity changes according to the alignment state of molecules; when molecules are aligned in one direction and take on polarity, thermal conductivity is improved, and when the alignment of molecules is disrupted and polarity disappears, thermal conductivity is lowered.

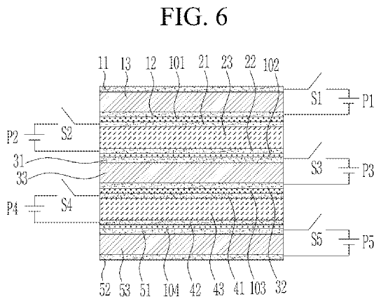

FIG. 6 is a cross-sectional view of a multi-layered bidirectional solid-state cooler according to another embodiment.

The multi-layered bidirectional solid-state cooler of FIG. 6 includes two electrocaloric layers 23, 43 and three thermal control layers 13, 33, 53. Electrocaloric layer control electrodes 21, 22, 41, 42 are disposed on both surfaces of each electrocaloric layer 23, 43, and thermal switch layer control electrodes 11, 12, 31, 32, 51, 52 are disposed on both surfaces of each of the thermal control layers 13, 33, 53. Insulating layers 101, 102, 103, 104 are disposed between the electrocaloric layer control electrodes 21, 22, 41, 42 and the thermal switch layer control electrodes 12, 31, 32, 51. Power supply voltages P2, P4 and switches S2, S4 are connected between the two pairs of electrocaloric layer control electrodes 21, 22, 41, 42, respectively. Power supply voltages P1, P3, P5 and switches S1, S3, S5 are connected between the three pairs of thermal switch layer control electrodes 11, 12, 31, 32, 51, 52, respectively.

The insulating layers 101, 102, 103, 104 located between the electrocaloric layer control electrodes 21, 22, 41, 42 and the thermal switch layer control electrodes 12, 31, 32, 51 may be omitted. That is, the electrocaloric layer control electrodes 21, 22, 41, 42 and the thermal switch layer control electrodes 12, 31, 32, 51 may be integrally formed, and one control electrode may be used for both the control of the electrocaloric layer and the control of the thermal switch layer located on both sides thereof.

The electrocaloric layers 23, 43 use a material whose internal entropy decreases or increases depending on whether or not an electric field is applied, and examples thereof include PMN-PT series or PST (lead scandium tantalate, Pb(ScₓTa₁₋ₓ)O₃) series and the like.

The thermal control layers 13, 33, 53 use a material whose thermal conductivity changes depending on whether or not an electric field is applied or the intensity of the electric field, and examples thereof include GeTeO₃, PbZrO₃, KNbO₃, PbTiO₃, BiFeO₃, PbZrO₃, PbTiZrNbNiO₃, PbZrTiO₃, etc.

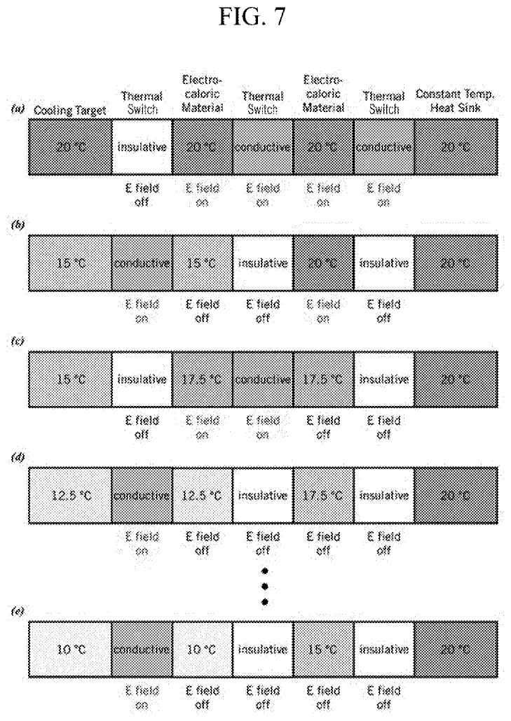

FIG. 7 is a diagram showing the operation flow of a multi-layered bidirectional solid-state cooler according to another embodiment.

Referring to FIG. 7, the operation flow of the multi-layered bidirectional solid-state cooler according to another embodiment will be described in more detail. It is assumed that the lower side of the multi-layered bidirectional solid-state cooler of FIG. 6 is a cooling target, and the upper side is a heat sink where the temperature is kept constant.
(a) In a state where an electric field is not applied to the lowermost thermal switch layer 53 (E field off) and an electric field is applied to the remaining two thermal control layers 13, 33 (E field on), an electric field is applied to the two electrocaloric layers 23, 43 (E field on) to make the temperature of the electrocaloric layers 23, 43 the same as the temperature of the heat sink (e.g., 20 °C).
(b) In a state where an electric field is applied to the lowermost thermal switch layer 53 (E field on) and the electric field that was applied to the remaining two thermal control layers 13, 33 is removed (E field off), when the electric field that was applied to the lower electrocaloric layer 43 is removed (E field off), the entropy of the lower electrocaloric layer 43 increases while absorbing heat, so the temperature of the lower electrocaloric layer 43 drops. At this time, heat is conducted from the cooling target to the lower electrocaloric layer 43 through the lowermost thermal switch layer 53, so the temperature of the cooling target goes down (e.g., 15 °C).
(c) In a state where an electric field is not applied to the lowermost thermal switch layer 53 and the uppermost thermal switch layer 13 (E field off) and an electric field is applied to the middle thermal switch layer 33 (E field on), when an electric field is applied to the lower electrocaloric layer 43 (E field on) and the electric field that was applied to the upper electrocaloric layer 23 is removed (E field off), the entropy of the lower electrocaloric layer 43 decreases while its temperature rises, and the entropy of the upper electrocaloric layer 23 increases while its temperature drops, so heat moves from the lower electrocaloric layer 43 to the upper electrocaloric layer 23, and as a result, the temperatures of the lower electrocaloric layer 43 and the upper electrocaloric layer 23 reach equilibrium (e.g., 17.5 °C).
(d) Again, in a state where an electric field is applied to the lowermost thermal switch layer 53 (E field on) and the electric field that was applied to the remaining two thermal control layers 13, 33 is removed (E field off), when the electric field that was applied to the lower electrocaloric layer 43 is removed (E field off), the entropy of the lower electrocaloric layer 43 increases while absorbing heat, so the temperature of the lower electrocaloric layer 43 drops. At this time, since the temperature of the lower electrocaloric layer 43 drops from 17.5 °C, it drops lower than in step (b). Along with this, heat is conducted from the cooling target to the lower electrocaloric layer 43 through the lowermost thermal switch layer 53, so the temperature of the cooling target further goes down (e.g., 12.5 °C).
(e) By repeating the above process, the temperature of the cooling target can be lowered twice as much as the temperature that can be lowered when only one electrocaloric layer is arranged (e.g., 10 °C).

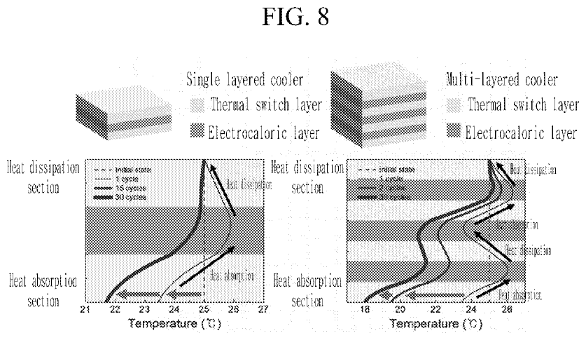

FIG. 8 is a conceptual diagram showing a process in which cooling proceeds when an electrocaloric material is applied as a single layer and when an electrocaloric material is applied as multiple layers.

When the electrocaloric material is applied as a single layer, even if the cooling cycle is repeated, cooling cannot proceed beyond the coolable temperature determined according to the characteristics of the corresponding electrocaloric material. However, when the electrocaloric material is applied as multiple layers, cooling can proceed by a value obtained by multiplying the number of layers by the coolable temperature determined according to the characteristics of the corresponding electrocaloric material.

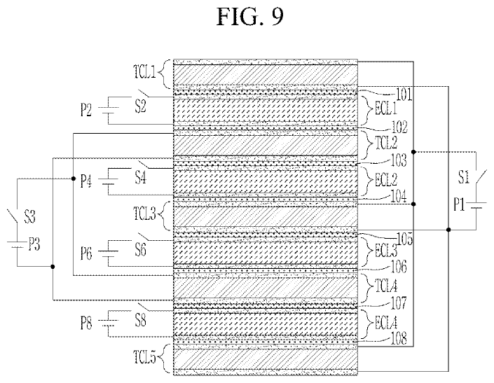

FIG. 9 is a cross-sectional view of a multi-layered bidirectional solid-state cooler according to another embodiment.

The multi-layered bidirectional solid-state cooler of FIG. 9 may have a structure in which two electrocaloric layer units ECL3, ECL4 and two thermal switch layer units TCL4, TCL5 are additionally coupled to the multi-layered bidirectional solid-state cooler according to the embodiment of FIG. 6. That is, it may have a structure in which four electrocaloric layer units ECL1, ECL2, ECL3, ECL4 are sandwiched between five thermal switch layer units TCL1, TCL2, TCL3, TCL4, TCL5. Here, each thermal switch layer unit TCL1, TCL2, TCL3, TCL4, TCL5 includes a thermal switch layer and a pair of control electrodes on both sides thereof, and each electrocaloric layer unit ECL1, ECL2, ECL3, ECL4 includes an electrocaloric layer and a pair of control electrodes on both sides thereof. Insulating layers 101, 102, 103, 104, 105, 106, 107, 108 may be located between adjacent thermal switch layer units TCL1, TCL2, TCL3, TCL4, TCL5 and electrocaloric layer units ECL1, ECL2, ECL3, ECL4.

Among the five thermal switch layer units TCL1, TCL2, TCL3, TCL4, TCL5, the odd-numbered thermal switch layer units TCL1, TCL3, TCL5 can be driven simultaneously, and the even-numbered thermal switch layer units TCL2, TCL4 can also be driven simultaneously. As shown in FIG. 9, the positive electrodes and negative electrodes of the odd-numbered thermal switch layer units TCL1, TCL3, TCL5 can be tied respectively and connected to one power source P1 and one switch S1 to be driven simultaneously. However, it is not mandatory to tie the control electrodes of the thermal switch layer units TCL1, TCL2, TCL3, TCL4, TCL5 and connect them to one power source P1 and one switch S1 for simultaneous driving, and each of the thermal switch layer units TCL1, TCL2, TCL3, TCL4, TCL5 may be connected to a separate power source and switch, and the driving timing of the switches may be controlled to turn on/off simultaneously.

In addition, the voltages applied to the five thermal switch layer units TCL1, TCL2, TCL3, TCL4, TCL5 may have a phase difference so that they are driven with a predetermined time difference.

The electrocaloric layer units ECL1, ECL2, ECL3, ECL4 can also be driven simultaneously by pairing some of them. For example, the odd-numbered electrocaloric layer units ECL1, ECL3 can be driven simultaneously, and the even-numbered electrocaloric layer units ECL2, ECL4 can be driven simultaneously.

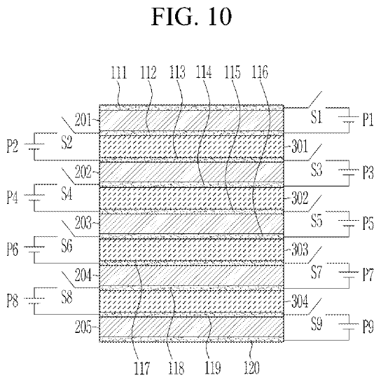

FIG. 10 is a cross-sectional view of a multi-layered bidirectional solid-state cooler according to another embodiment.

The multi-layered bidirectional solid-state cooler of FIG. 10 includes four electrocaloric layers 301, 302, 303, 304 and five thermal control layers 201, 202, 203, 204, 205, and includes ten control electrodes 111, 112, 113, 114, 115, 116, 117, 118, 119, 120. Control electrodes 112, 113, 114, 115, 116, 117, 118, 119 located between the electrocaloric layers 301, 302, 303, 304 and the thermal control layers 201, 202, 203, 204, 205 are all used for the control of the electrocaloric layers 301, 302, 303, 304 and the control of the thermal control layers 201, 202, 203, 204, 205 located on both sides thereof. By properly controlling the operation of the switches S1, S2, S3, S4, S5, S6, S7, S8, S9, all of the electrocaloric layers 301, 302, 303, 304 and the thermal control layers 201, 202, 203, 204, 205 can be controlled using the shared control electrodes 112, 113, 114, 115, 116, 117, 118, 119.

As described above, a structure that allows one control electrode to be used for both the control of the electrocaloric layer and the control of the thermal switch layer located on both sides thereof can also be applied to the multi-layered bidirectional solid-state coolers according to the embodiment of FIG. 1 and the embodiment of FIG. 6.

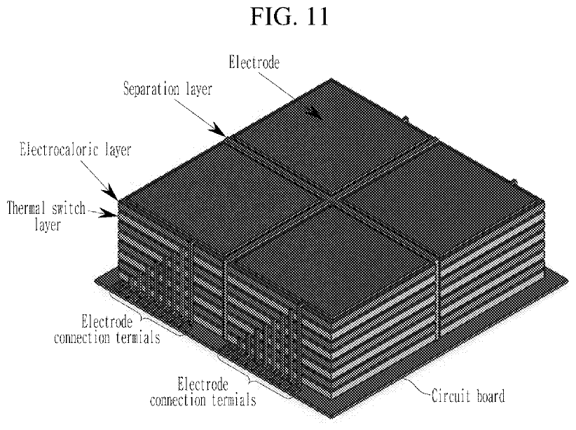

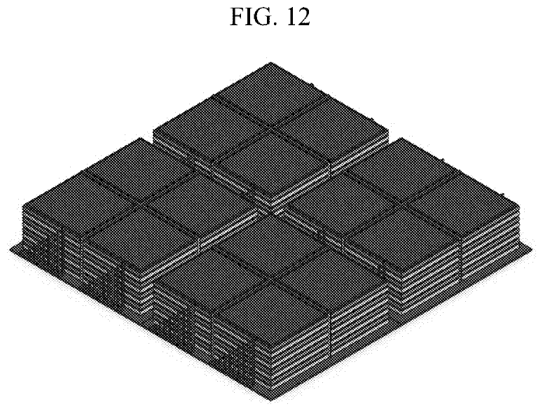

FIG. 11 and FIG. 12 are perspective views of multi-layered bidirectional solid-state coolers according to other embodiments.

The multi-layered bidirectional solid-state cooler according to the embodiment of FIG. 11 is a configuration in which four solid-state coolers of FIG. 10 are arranged in a 2×2 matrix on one circuit board. A separation layer for improving insulation and structural stability may be located between the four solid-state coolers. The separation layer may include an insulating material such as resin. The number or arrangement form of solid-state coolers disposed together on one circuit board can be variously modified as needed. For example, three or six may be disposed together on one circuit board, and they may be arranged in a single row rather than a matrix, or arranged in an ‘L’ shape.

The circuit board may include wiring and switching elements to supply and block power to the solid-state cooler, and may include a portion made of a material with good thermal conductivity, such as metal, to function as a heat sink. Electrode connection terminals are disposed on the circuit board to electrically connect between the wiring of the circuit board and the control electrodes.

Since the four solid-state coolers can each be driven independently, they can be cooled to different temperatures, or only some of them can be cooled.

The multi-layered bidirectional solid-state cooler according to the embodiment of FIG. 12 is an expanded configuration in which four solid-state coolers according to the embodiment of FIG. 11 are arranged in a 2×2 matrix. The number or arrangement form of solid-state coolers disposed together can be variously modified as needed.

While the embodiments of the present invention have been described in detail above, the scope of the rights of the present invention is not limited thereto, and various modifications and improvements by those skilled in the art using the basic concept of the present invention defined in the following claims also fall within the scope of the rights of the present invention.

What is claimed is:

1. A multi-layered bidirectional solid-state cooler comprising:
an electrocaloric layer;
a first thermal switch layer disposed on a first surface of the electrocaloric layer; and
a second thermal switch layer disposed on a second surface of the electrocaloric layer,
wherein the electrocaloric layer performs heat generation or heat absorption by decreasing or increasing entropy depending on whether or not an electric field is applied, and
the first thermal switch layer and the second thermal switch layer each cover ⅔ or more of the first surface and the second surface of the electrocaloric layer, and thermal conductivity changes depending on whether or not an electric field is applied or intensity of the electric field.

2. The multi-layered bidirectional solid-state cooler of claim 1,
wherein the electrocaloric layer includes a ceramic material having a complex perovskite structure of a PMN-PT series or a PST series.

3. The multi-layered bidirectional solid-state cooler of claim 1,
further comprising: a first electrocaloric layer control electrode and a second electrocaloric layer control electrode disposed on both surfaces of the electrocaloric layer, respectively; and
a thermal switch layer control electrode disposed on both surfaces of each of the first and second thermal control layers.

4. The multi-layered bidirectional solid-state cooler of claim 3,
wherein an electrically insulating layer is disposed between the electrocaloric layer control electrode and the thermal switch layer control electrode.

5. The multi-layered bidirectional solid-state cooler of claim 3,
wherein the electrocaloric layer control electrode and the thermal switch layer control electrode are integrally formed so that one electrode is used simultaneously for control of the electrocaloric layer and the thermal switch layer located on both sides.

6. The multi-layered bidirectional solid-state cooler of claim 1,
wherein cooling is achieved by repeating an operation cycle in which heat is released and a temperature rise occurs as internal entropy decreases when an electric field is applied to the electrocaloric layer, and heat is absorbed and a temperature drop occurs as internal entropy increases when the electric field is removed.

7. The multi-layered bidirectional solid-state cooler of claim 1,
wherein the first thermal switch layer and the second thermal switch layer have maximum thermal conductivity when a first voltage is applied, and minimum thermal conductivity when a second voltage is applied.

8. The multi-layered bidirectional solid-state cooler of claim 7,
wherein the second voltage is 0V.

9. The multi-layered bidirectional solid-state cooler of claim 1,
wherein in the thermal control layer, an alignment state of molecules changes depending on whether or not an electric field is applied or intensity, and due to this, thermal conductivity is improved or lowered.

10. The multi-layered bidirectional solid-state cooler of claim 1,
wherein a switch and a power supply voltage are connected between each pair of control electrodes of the electrocaloric layer and the thermal switch layer to selectively control application or blocking of an electric field.

11. A multi-layered bidirectional solid-state cooler comprising:
a plurality of thermal control layers; and
a plurality of electrocaloric layers disposed between the plurality of thermal control layers,
wherein the thermal switch layer and the electrocaloric layer have a structure in which they are alternately stacked,
the plurality of electrocaloric layers perform heat generation or heat absorption by decreasing or increasing entropy depending on whether or not an electric field is applied, and
the plurality of thermal control layers change thermal conductivity depending on whether or not an electric field is applied or intensity of the electric field.

12. The multi-layered bidirectional solid-state cooler of claim 11,
further comprising: a plurality of electrocaloric layer control electrodes disposed on both surfaces of each of the plurality of electrocaloric layers; and
a plurality of thermal switch layer control electrodes disposed on both surfaces of each of the plurality of thermal control layers.

13. The multi-layered bidirectional solid-state cooler of claim 12,
wherein an electrically insulating layer is disposed between the electrocaloric layer control electrode and the thermal switch layer control electrode.

14. The multi-layered bidirectional solid-state cooler of claim 12,
wherein the electrocaloric layer control electrode and the thermal switch layer control electrode are integrally formed so that one electrode is used simultaneously for control of the electrocaloric layer and the thermal switch layer located on both sides.

15. The multi-layered bidirectional solid-state cooler of claim 12,
wherein the plurality of electrocaloric layers and the plurality of thermal control layers are capable of independent control by individually connecting a power source and a switch to each control electrode.

16. A multi-layered bidirectional solid-state cooler comprising:
a circuit board;
a plurality of solid-state cooling elements disposed on the circuit board; and
a plurality of electrode connection terminals connecting between wiring of the circuit board and a plurality of control electrodes of the plurality of solid-state cooling elements,
wherein each of the plurality of solid-state cooling elements includes:
a plurality of thermal control layers; and
a plurality of electrocaloric layers disposed between the plurality of thermal control layers,
wherein the thermal switch layer and the electrocaloric layer have a structure in which they are alternately stacked,
the plurality of electrocaloric layers perform heat generation or heat absorption by decreasing or increasing entropy depending on whether or not an electric field is applied, and
the plurality of thermal control layers change thermal conductivity depending on whether or not an electric field is applied or intensity of the electric field.

17. The multi-layered bidirectional solid-state cooler of claim 16,
further comprising a separation layer located between the plurality of solid-state cooling elements and composed of an insulating material, and
each of the plurality of solid-state cooling elements is independently controlled.

18. The multi-layered bidirectional solid-state cooler of claim 16,
wherein the circuit board includes a portion composed of a material having excellent thermal conductivity, such as metal, to perform a heat sink function.

19. The multi-layered bidirectional solid-state cooler of claim 16,
wherein the plurality of solid-state cooling elements are arranged in a 2×2 matrix, a single row arrangement, or an L-shaped arrangement.

20. The multi-layered bidirectional solid-state cooler of claim 16,
including the multi-layered bidirectional solid-state cooler in plurality.
